(19) United States
(12) Patent Application Publication
(10) Pub. No.: US 2023/0290913 A1
(43) Pub. Date: Sep. 14, 2023

(54) LIGHT EMITTING MODULE

(71) Applicant: Lextar Electronics Corporation, Hsinchu City (TW)

(72) Inventor: Min-Chen CHIU, Hsinchu City (TW)

(21) Appl. No.: 18/167,156

(22) Filed: Feb. 10, 2023

(30) Foreign Application Priority Data
Mar. 10, 2022 (TW) 111108710

(51) Int. Cl. H01L 33/54; H01L 25/075; H01L 33/60

(52) U.S. Cl. CPC H01L 33/54; H01L 25/0753; H01L 33/60

(57) ABSTRACT

A light emitting module is provided. The light emitting module includes a substrate, light emitting elements, an encapsulant material and dimming structures. The light emitting elements are disposed over the substrate. The encapsulant material covers the light emitting elements and the substrate, and the encapsulant material has an encapsulant height H. The dimming structures are disposed over the encapsulant material or embedded in the encapsulant material. The dimming structures have a maximum dimming thickness h. The encapsulant thickness H and the maximum dimming thickness h satisfy the following relationship: 0.01≤h/H≤1.

### CROSS REFERENCE TO RELATED APPLICATIONS

This application claims priority of Taiwan Patent Application No. 111108710 filed on Mar. 10, 2022, the entirety of which is incorporated by reference herein.

### BACKGROUND

### Technical Field

The present disclosure relates to a light emitting module, and in particular it relates to a light emitting module including dimming structures.

### Description of the Related Art

Light emitting diodes (LEDs) have gradually replaced traditional light sources in recent years due to their advantages, such as their small size, high brightness, and low energy consumption. Light emitting diodes have been widely used in backlight modules as light emitting elements.

The design for the current backlight modules includes light emitting elements mounted on a circuit board, which has the disadvantage of a short light transmission path. Therefore, when the spacing between light emitting elements is too large, a dark area appears between the light emitting elements, resulting in a poor visual experience. Although the above problem can be improved by reducing the spacing between the light emitting diodes, the number of light emitting diodes is increased when the spacing is reduced, which results in a cost increase.

In addition, since LED chips have a high directivity, the brightness of the light directly above the LED chips is relatively high in a conventional light emitting device. Therefore, the light output of the light emitting device is uneven. To sum up, there is a need for a light emitting module that can solve the above problems.

### BRIEF SUMMARY

The present disclosure provides a light emitting module. The light emitting module includes a substrate, light emitting elements, an encapsulant material and dimming structures. The light emitting elements are disposed over the substrate. The encapsulant material covers the light emitting elements and the substrate, and the encapsulant material has an encapsulant height H. The dimming structures are disposed over the encapsulant material or embedded in the encapsulant material, wherein the dimming structures have a maximum dimming thickness h. The encapsulant thickness H and the maximum dimming thickness h satisfy the following relationship: 0.01≤h/H≤1.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a three-dimensional schematic diagram of a light emitting module, in accordance with some embodiments of the present disclosure.

FIG. 1B illustrates a cross-sectional view corresponding to line BB′ of FIG. 1A, in accordance with some embodiments of the present disclosure.

FIG. 1C illustrates a cross-sectional view of a light emitting module, in accordance with some other embodiments of the present disclosure.

FIG. 1D illustrates a cross-sectional view of a light emitting module, in accordance with some other embodiments of the present disclosure.

FIG. 2A illustrates a three-dimensional schematic diagram of a light emitting module, in accordance with some other embodiments of the present disclosure.

FIG. 2B illustrates a cross-sectional view corresponding to line BB′ of FIG. 2A, in accordance with some embodiments of the present disclosure.

FIG. 3A illustrates a three-dimensional schematic diagram of a light emitting module, in accordance with some other embodiments of the present disclosure.

FIG. 3B illustrates a cross-sectional view corresponding to line BB′ of FIG. 3A, in accordance with some embodiments of the present disclosure.

FIG. 3C illustrates a cross-sectional view corresponding to line CC′ of FIG. 3A, in accordance with some embodiments of the present disclosure.

FIG. 4A illustrates a three-dimensional schematic diagram of a light emitting module, in accordance with some other embodiments of the present disclosure.

FIG. 4B illustrates a cross-sectional view corresponding to line BB′ of FIG. 4A, in accordance with some embodiments of the present disclosure.

FIG. 4C illustrates a cross-sectional view corresponding to line CC′ of FIG. 4A, in accordance with some embodiments of the present disclosure.

FIG. 5A is a light emitting image resulted from a conventional light emitting module during an actual test.

FIG. 5B is a light emitting image resulted from a light emitting module of the present disclosure during an actual test.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, and “substantially” used herein generally refer to a given value or a range within 20 percent, within 10 percent, within 5 percent, within 3 percent, within 2 percent, within 1 percent, or within 0.5 percent. It should be noted that the amounts provided in the specification are approximate amounts, which means that even “about”, “approximate”, or “substantially” are not specified, the meanings of “about”, “approximate”, or “substantially” are still implied.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The present disclosure provides a light emitting module including lighting emitting elements and dimming structures located above the light emitting elements respectively wherein the dimming structures have the effect of partially transmitting light and partially reflecting light. Since the dimming structures of the present disclosure have portions with different thicknesses, they can be used to adjust the brightness of the light above the light emitting elements, so that the light output of the light emitting module as a whole is more uniform. Therefore, the light emitting module of the present disclosure has excellent brightness and uniformity, and can reduce the usage of light emitting diodes, thereby reducing the manufacturing cost.

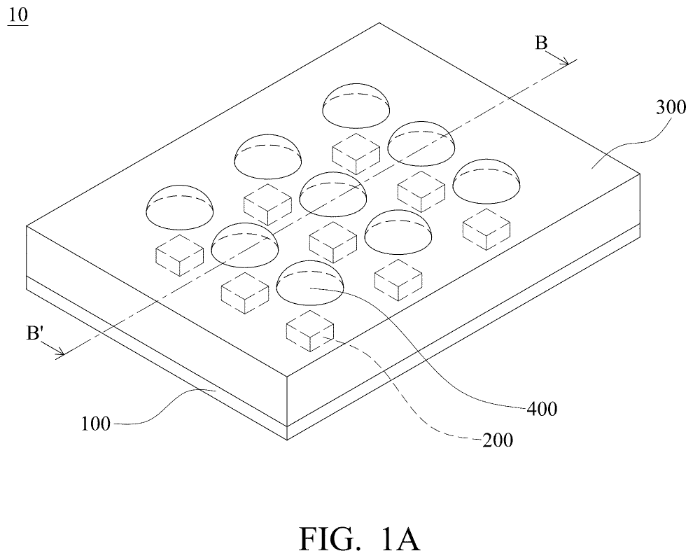

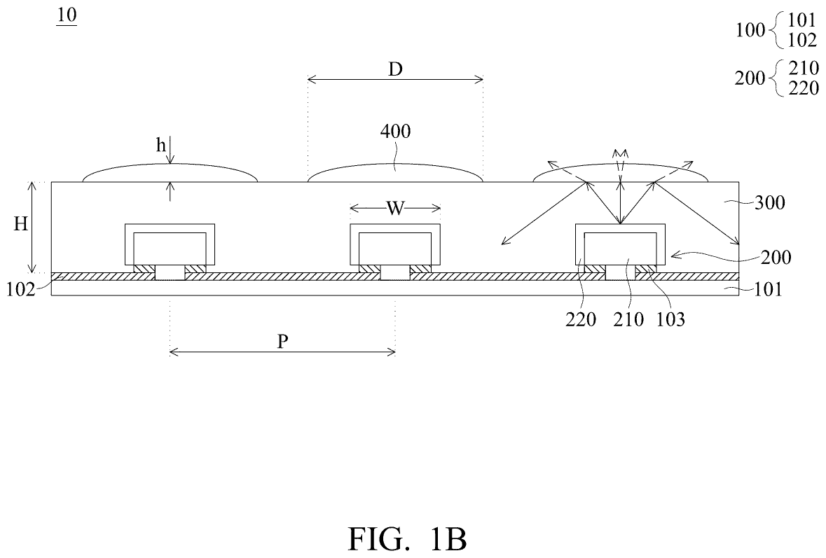

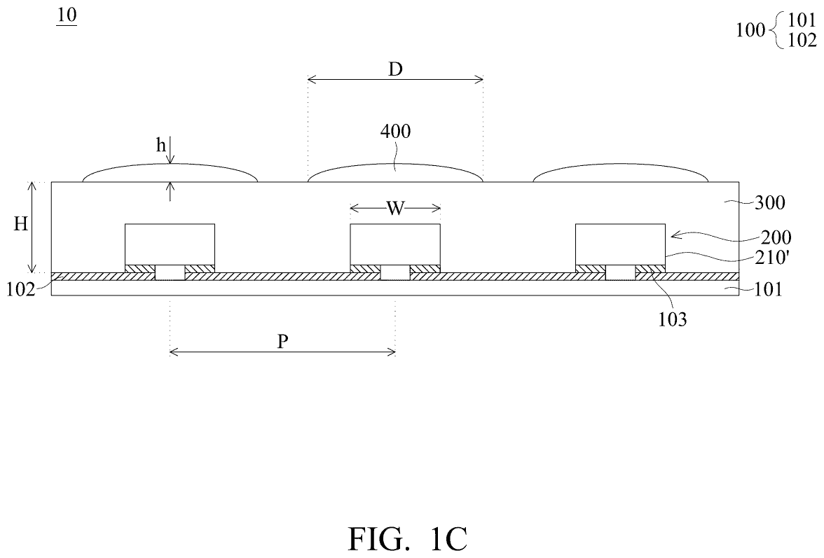

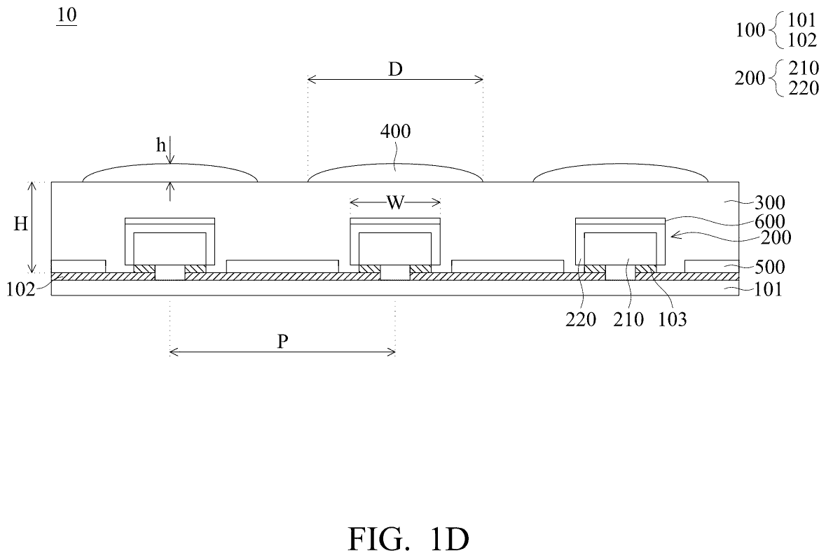

Referring to FIGS. 1A and 1B, FIG. 1A is a three-dimensional schematic diagram of a light emitting module according to some embodiments of the present disclosure, and FIG. 1B is a cross-sectional view corresponding to line BB′ of FIG. 1A. As shown in FIGS. 1A and 1B, a light emitting module 10 may include a substrate 100, light emitting elements 200, an encapsulant material 300, and dimming structures 400. A detailed description of the above-mentioned elements will be described below.

In some embodiments, the substrate 100 includes a base 101. For example, the base 101 may be a transparent substrate or an opaque substrate. In some embodiments, the base 101 is a flexible substrate. Therefore, the light emitting module 10 may be a light emitting module in the form of a highly curved backlight. In other embodiments, the base 101 is a rigid substrate. For example, the material of the base 101 may be resin, sapphire, silicon, glass, metal, ceramic, etc. As shown in FIG. 1A, the substrate 100 may be a rectangular substrate.

As shown in FIG. 1B, the substrate 100 may further include a conductive layer 102 on the base 101. As a result, the substrate 100 can be electrically connected to the light emitting elements 200 through the conductive layer 102. In some embodiments, as shown in FIG. 1B, the light emitting elements 200 are disposed over the substrate 100 in a flip chip manner, and bonding members 103 are located between positive electrodes and negative electrodes of the light emitting elements 200 and the conductive layer 102. The positive electrodes and the negative electrodes of the light emitting elements 200 are electrically connected to the conductive layer 102 through the bonding members 103. In some embodiments, the conductive layer 102 comprises conductor wiring lines.

The material of the bonding members 103 is a conductive material, which may include: Au-containing alloys, Ag-containing alloys, Pd-containing alloys, In-containing alloys, Pb—Pd-containing alloys, Au—Ga-containing alloys, Au—Sn-containing alloys, Sn-containing alloys, Sn—Cu-containing alloys, Sn—Cu—Ag-containing alloys, Au—Ge-containing alloys, Au—Si-containing alloys, Al-containing alloys, Cu—In-containing alloys, or other metallic materials. In one embodiment, the bonding members 103 are mixtures comprising metal and flux.

It should be noted that FIG. 1A is only used to schematically illustrate the structure of the light emitting module 10, wherein the structure of the conductive layer 102, the bonding members 103 and other structures are not shown in detail. In addition, in some embodiments, the substrate 100 further includes an insulating material (not shown) below the base 101.

As shown in FIGS. 1A and 1B, light emitting elements 200 are disposed on the substrate 100. The light emitting elements 200 of the present disclosure may include light emitting diode chips or chip-scale package light emitting diodes (CSP LEDs). In some embodiments, the light emitting elements 200 include light emitting diode chips capable of emitting a specific wavelength. For example, the light emitting elements 200 may include light emitting diode chips emitting blue light or ultraviolet light. In addition, the light emitting elements 200 may include a sub-millimeter light emitting diode chip (Mini LED chip), or a micro light emitting diode chip (Micro LED chip). The side length dimension of the above-mentioned “Mini LED chip” may be about 100 μm, 150 μm, 200 μm, 250 μm, 300 μm, 350 μm or 400 μm. The side length dimension of the above-mentioned “micro-LED chip” may be about 100 μm or less, for example, about 30 μm, 40 μm, 50 μm, 60 μm, 70 μm, 80 μm or 90 μm or less. In some embodiments, the light emitting elements 200 may be in a package with a reflector.

The light emitting elements 200 in some embodiments of the present disclosure may also include light emitting diode chips or chip-scale package light emitting diodes (CSP LEDs). As shown in FIG. 1B, each of the light emitting elements 200 using CSP LED includes a light emitting diode (LED) chip 210 and a wavelength conversion layer 220 covering a top surface and side surfaces of the LED chip 210.

The light emitting diode chip 210 is capable of emitting a specific wavelength. The wavelength conversion layer 220 may include quantum dot materials, phosphors, other suitable materials, or combinations thereof. The light emitting module 10 may serve as the backlight of a display. A light emitting module 10 emitting white light is taken as an example. The light emitting diode chip 210 may be a blue LED chip for emitting blue light, while the wavelength conversion layer 220 includes yellow phosphors, which absorbs part of the blue light and converts it into yellow light, and the yellow light is mixed with part of the blue light to produce white light. Alternatively, the wavelength conversion layer 220 includes red and green wavelength conversion materials to absorb part of the blue light and convert it into red light and green light respectively, and the red light and green light are mixed with part of the blue light to generate white light.

In some other embodiments, as shown in FIG. 1C, each of the light emitting elements 200 may not have the wavelength conversion layer, and may include a light emitting diode chip 210′. In the embodiments in which each of the light emitting elements 200 does not have a wavelength conversion layer, a wavelength conversion material such as phosphors or a quantum dot material may be added to the subsequently formed encapsulant material 300, wherein the encapsulant material 300 covers the light emitting elements 200 and the substrate 100. Therefore, the light emission wavelength from the light emitting diode chip 210′ is converted. In another embodiment, a wavelength conversion material may also be integrated into the light emitting diode chip 210′, thereby converting the light emission wavelength from the light emitting diode chip 210′.

In some embodiments, integrated circuit chips (not shown) may be disposed on the surface of the substrate 100, and each of the integrated circuit chips controls the light emitting elements 200 respectively. In some embodiments, the integrated circuit chips and the light emitting diode chips are on the same surface of the substrate 100 and may be covered by the encapsulant material 300. In some embodiments, the light emitting diode chips are on the upper surface of the substrate 100, and the integrated circuit chips are on the lower surface of the substrate 100. It should be noted that, for the purpose of illustration, the following embodiments of the present disclosure will generally be described with the light emitting elements 200 having the wavelength conversion layers 220. In fact, those with ordinary skill in the art may adjust the configuration of the light emitting elements according to the design requirements of the light emitting module, which is not limited in the present disclosure.

Referring to FIGS. 1A and 1B, the encapsulant material 300 integrally covers the light emitting elements 200 and the substrate 100, and the encapsulant material 300 has an encapsulant thickness H. Specifically, the encapsulant material 300 may have a rough or smooth upper surface, which is not limited in the present disclosure. In some embodiments, as shown in FIG. 1B, the encapsulant material has two side surfaces, which are coplanar with the two side surfaces of the substrate 100, respectively. The present disclosure does not specifically limit the composition of the encapsulant material 300. The encapsulant material 300 may include silicone resin, epoxy, acrylic, other suitable transparent materials, or combinations thereof. In some embodiments, the refractive index of the encapsulant material 300 is about 1.49 to about 1.6.

Referring to FIGS. 1A and 1B again, the dimming structures 400 are disposed on the surface of the encapsulant material 300, wherein the dimming structures 400 include portions with different thicknesses, and the dimming structures have a maximum dimming thickness h. In the embodiments of the present disclosure, the encapsulant thickness H and the maximum dimming thickness h satisfy the following relationship: 0.01≤h/H≤1. In some embodiments, the encapsulant thickness H and the maximum dimming thickness h satisfy the following relationship: 0.01≤h/H≤0.4. In some embodiments, the encapsulant thickness H and the maximum dimming thickness h satisfy the following relationship: 0.1≤h/H≤0.25.

As shown in FIGS. 1A and 1B, each dimming structure 400 may be located above the respective light emitting element 200. In some embodiments, the position of each dimming structure 400 having the maximum dimming thickness h overlaps with a light emitting element 200 in the normal direction of the substrate 100.

The dimming structures 400 have the effect of partially transmitting light and partially reflecting light, and can be used to adjust the brightness of the light emitted by the light emitting elements 200. Specifically, since the LED chips have high directivity, in conventional light emitting devices, the brightness of the light directly above the LED chips is relatively high, which makes the light output of the light emitting devices uneven. According to the dimming structures 400 in various embodiments of the present disclosure, the brightness of the light above the light emitting elements can be adjusted, so that the light output of the light emitting module as a whole is more uniform.

The dimming structures 400 may include a reflective material and a resin material. The reflective material may include metal oxide particles such as titanium oxide, aluminum oxide, zirconium oxide, silicon oxide, other suitable metal oxides, or combinations thereof. The resin material may include silicone resin, epoxy, acrylic, other suitable transparent materials, or combination thereof. The dimming structures 400 appear white in appearance.

In some embodiments, since the reflective material (such as metal oxide particles) is uniformly distributed throughout the dimming structures 400, the refractive index inside the dimming structures 400 is uniform. Specifically, when the refractive index inside the dimming structures 400 is uniform, the inside of the dimming structures 400 does not have any interface with a sharp change in the refractive index.

The transmission path of the light from a light emitting elements 200 is shown by the arrows in FIG. 1B, a part of the light emitted by the light emitting elements 200 passes through and transmits the dimming structures 400, and another part of the light is reflected back into the encapsulant material 300 by the dimming structures 400. As a result, the transmission distance of the light emitted by the light emitting elements 200 in the encapsulant material 300 can be increased, and the light output of the light emitting module can be more uniform. In some embodiments, the top surface of the encapsulant material 300 has a rough surface, so as to destroy the total reflection of light at the interface between the encapsulant material 300 and the dimming structures 400 or air, thereby increasing the light output efficiency.

Referring to FIG. 1D, in some embodiments, an insulating layer 500 may also be disposed on the substrate 100. In some embodiments, since the insulating layer 500 covers the substrate 100 and the exposed conductive layer 102 at the position where the light emitting element 200 is not present, the conductive layer can be prevented from being oxidized. In addition, the appearance of the insulating layer 500 may be white, which has the function of reflecting light. Therefore, disposing both the dimming structures 400 and the insulating layer 500 can further increase the transmission distance of the light emitted by the light emitting elements 200 in the encapsulant material 300, and make the light output of the light emitting module 10 more uniform. As a result, the uniformity of light output can be maintained without reducing or increasing the spacing between the light emitting diodes. The material of the insulating layer 500 may include epoxy resin, silicone resin, urethane resin, oxetane resin, acrylic glue, polycarbonate, polyimide. Other suitable white reflective materials can be added to the insulating layer 500.

Continuing to refer to FIG. 1D, in some embodiments, reflective layers 600 may be provided on the upper surface of the light emitting elements 200. The reflective layers 600 can reflect the light from the light extraction surface (such as the upper surfaces of the light emitting elements 200), increase the distance of light transmission in the encapsulant material 300, and make the light output of the light emitting module 10 more uniform. Although the light emitting diode chips have a high directivity, the brightness of the light directly above the light emitting elements 200 can be reduced by disposing the reflective layers 600. As a result, the uniformity of light output can be maintained without reducing or increasing the spacing between the light emitting diodes. The reflective layers 600 may be a specular metal material, reflective sheets, white ink, or other suitable materials.

The relationship of the geometric dimensions between the dimming structures 400 and other elements of the light emitting module 10 will be described in detail below. As shown in FIG. 1B, in some embodiments, each dimming structure 400 has an outer diameter D, and the outer diameter D, the encapsulant thickness H and the maximum dimming thickness h satisfy the following relationship: 0<(H+h)/D<1. In some embodiments, the distance P between neighboring light emitting elements 200 and the outer diameter D of each dimming structure 400 satisfy the following relationship: 0<D/P<1. In some embodiments, the width W of the light emitting elements 200 is smaller than the outer diameter D of each dimming structure 400.

The present disclosure does not specifically limit the shape of the dimming structures 400 in a cross-section vertical to the substrate 100, as long as the dimming structures 400 include portions with different thicknesses. For example, in some embodiments, as shown in FIGS. 1A to 1D, the surface of each dimming structure 400 is a curved surface with a gradient slope. The position of such dimming structure 400 having the maximum dimming thickness h may overlap with each light emitting element 200 in the normal direction of the substrate 100. In some embodiments, the shape of the above-mentioned curved surface fits to the quadratic function: y=ax²+bx+c, wherein x is the position in the direction parallel to the substrate, y is the position in the direction perpendicular to the substrate, and a<0. In some embodiments, the absolute value |c| of the constant term of the quadratic function is equal to the maximum dimming thickness h.

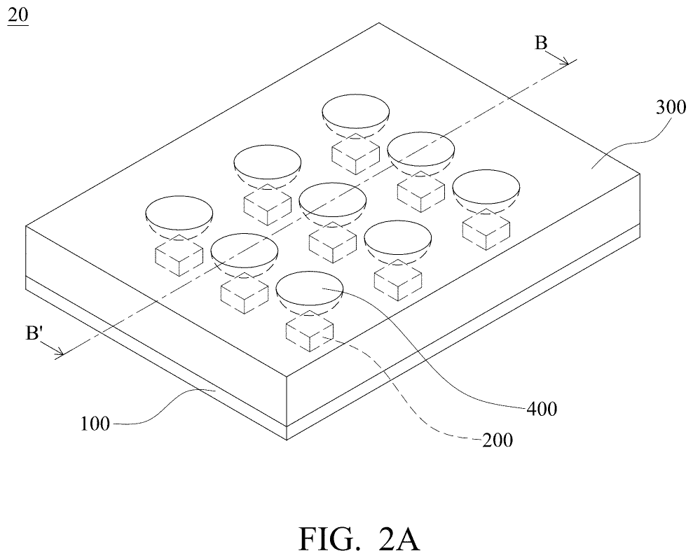

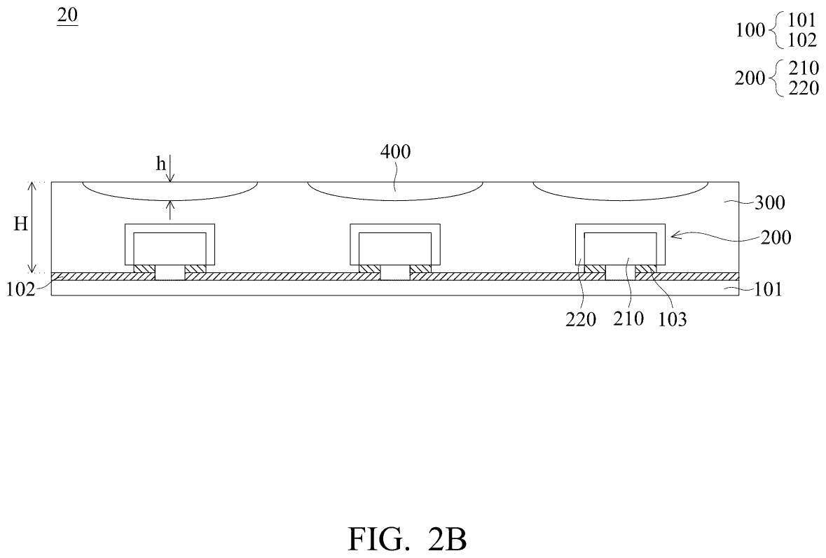

Although the dimming structures 400 are disposed on the upper surface of the encapsulant material 300 in the above embodiments, the present disclosure is not limited thereto. FIG. 2A is a three-dimensional schematic diagram of a light emitting module 20 according to some embodiments of the present disclosure, and FIG. 2B is a cross-sectional view corresponding to the line BB′ of FIG. 2A. As shown in FIGS. 2A and 2B, each of the dimming structures 400 having a curved surface with a gradual slope can be embedded in the encapsulant material 300. As a result, the thickness of the light emitting module 20 can be reduced.

In the embodiment of FIG. 2B, the relationship of the geometric dimensions between the dimming structures 400 and other elements of the light emitting module 20 is similar to that described in FIG. 1B, and the description thereof is omitted here for brevity. The shape of the curved surface of each of the dimming structures 400 embedded in the encapsulant material 300 also fits the quadratic function: y=ax²+bx+c, wherein x is the position in the direction parallel to the substrate, and y is the position in the direction perpendicular to the substrate, and a>0. In some embodiments, the absolute value |c| of the constant term of the quadratic function is equal to the maximum dimming thickness h.

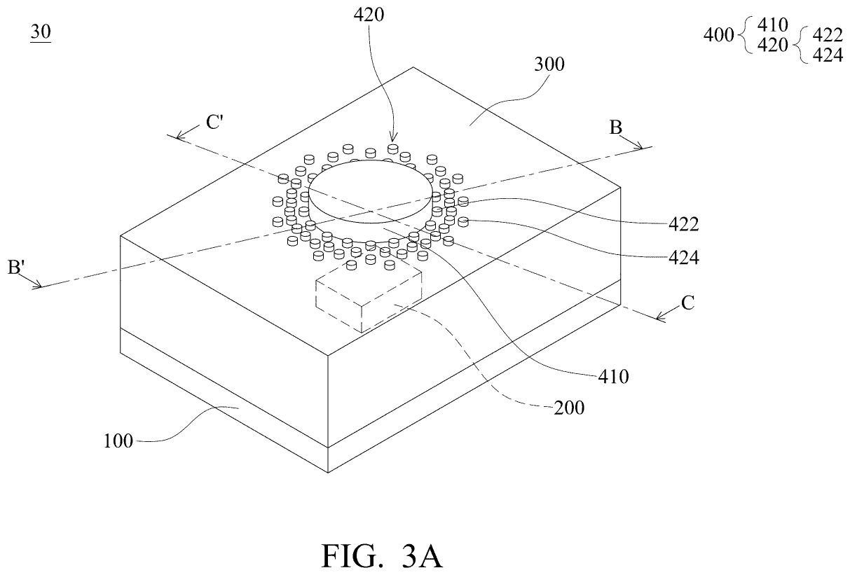

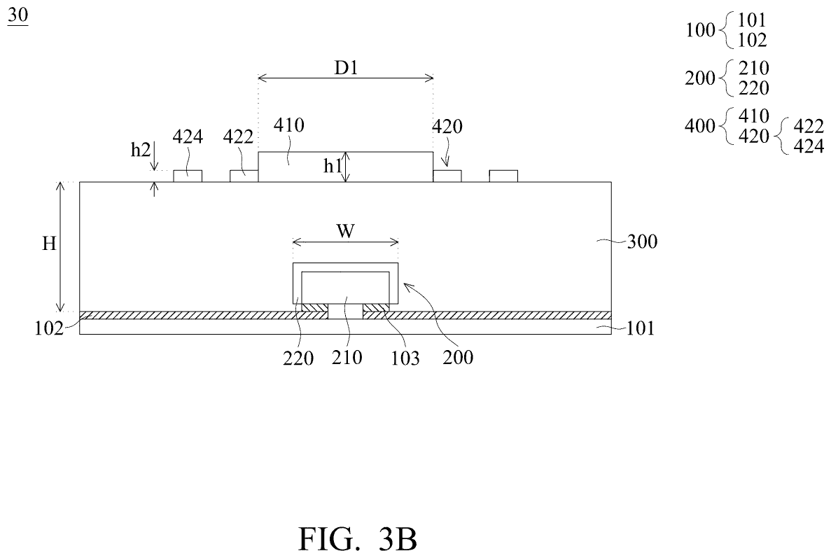

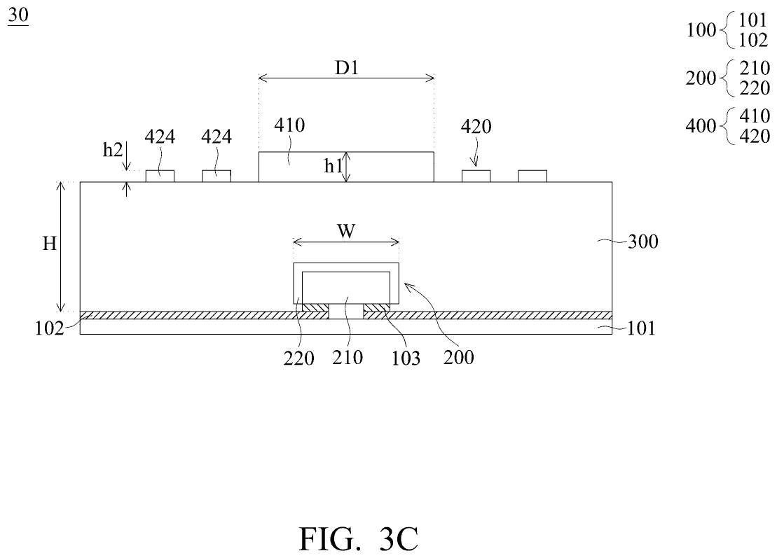

In some other embodiments of the present disclosure, as shown in FIGS. 3A to 3C, the dimming structure 400 of a light emitting module 30 includes a main dimming part 410 and a plurality of sub-dimming parts 420 surrounding the main dimming part 410. The main dimming part 410 and the sub-dimming parts 420 are used to increase the distance that the light emitted by the light emitting element 200 travels in the encapsulant material 300, so as to make the light output of the light emitting module 30 more uniform. The main dimming part 410 has a maximum dimming thickness h1, and the sub-dimming parts 420 disposed around the main dimming part 410 may have a thickness h2 smaller than the maximum dimming thickness h1. As shown in FIGS. 3B and 3C, the encapsulant thickness H and the maximum dimming thickness h1 satisfy the following relationship: 0.01≤h1/H≤1. In some further embodiments, the encapsulant thickness H and the maximum dimming thickness h1 satisfy the following relationship: 0.1≤h1/H≤0.25.

It should be understood that FIG. 3B is a cross-sectional view corresponding to line BB′ of FIG. 3A, and FIG. 3C is a cross-sectional view corresponding to line CC′ of FIG. 3A.

The sub-dimming parts 420 may include inner sub-dimming parts 422 in contact with the main dimming part 410, for example, two inner sub-dimming parts 422 in contact with the main dimming part 410 in FIG. 3B. As shown in FIGS. 3A and 3B, the inner sub-dimming parts 422 and the main dimming part 410 together form a stepped profile in a cross-sectional view (for example, in FIG. 3B).

The sub-dimming parts 420 may also include outer sub-dimming parts 424 separated from the main dimming part 410, for example, two outer sub-dimming parts 424 separated from the main dimming part 410 in FIG. 3C. As shown in FIGS. 3A and 3C, there are gaps of different sizes between each of the outer sub-dimming parts 424 and the main dimming part 410, thereby achieving a progressive dimming effect.

It should be understood that, although FIG. 3C only shows two inner sub-dimming parts 422 and two outer sub-dimming parts 424 disposed opposite to the main dimming part 410, the present disclosure does not limit the position of the sub-dimming parts 420 around the main dimming part 410 and their distance from the main dimming part 410. The light emitting module 30 may include sub-dimming parts 420 with various configurations according to design requirements.

As shown in FIGS. 3A to 3C, the dimming structure 400 may be located above the light emitting element 200. In some embodiments, the position of the dimming structures 400 having the maximum dimming thickness h1 overlaps with the light emitting element 200 in the normal direction of the substrate 100.

The relationship of the geometric dimensions between the dimming structures 400 and other elements of the light emitting module 30 will be described in detail below. As shown in FIGS. 3B and 3C, in some embodiments, the main dimming portion 410 of the dimming structure 400 has an outer diameter D1, and the outer diameter D1, the encapsulant thickness H and the maximum dimming thickness h satisfy the following relationship: 0<(H+h)/D1<1. In some embodiments, the distance P between neighboring light emitting elements 200 (not shown in FIGS. 3B and 3C) and the outer diameter D1 of the main dimming portion 410 satisfy the following relationship: 0<D1/P<1. In some embodiments, the outer diameter D1 of the main dimming portion 410 is greater than the width W of the light emitting element 200.

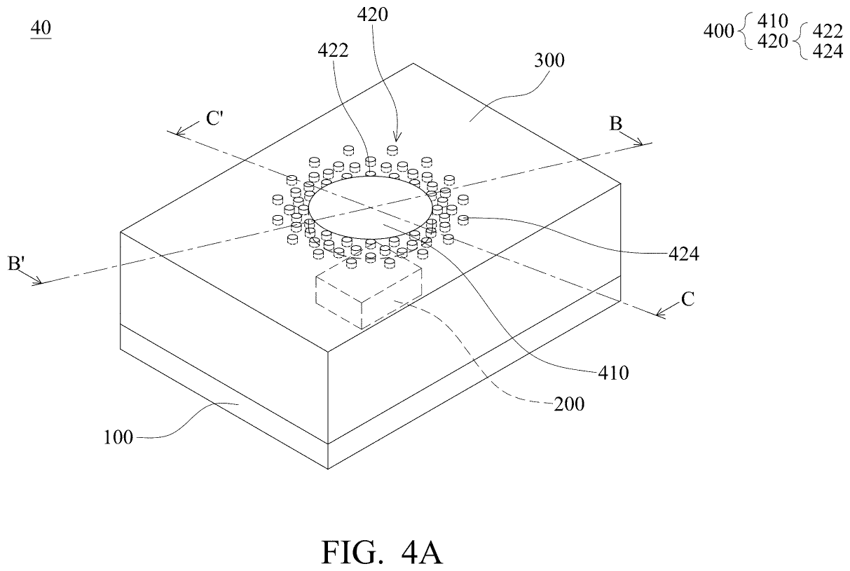

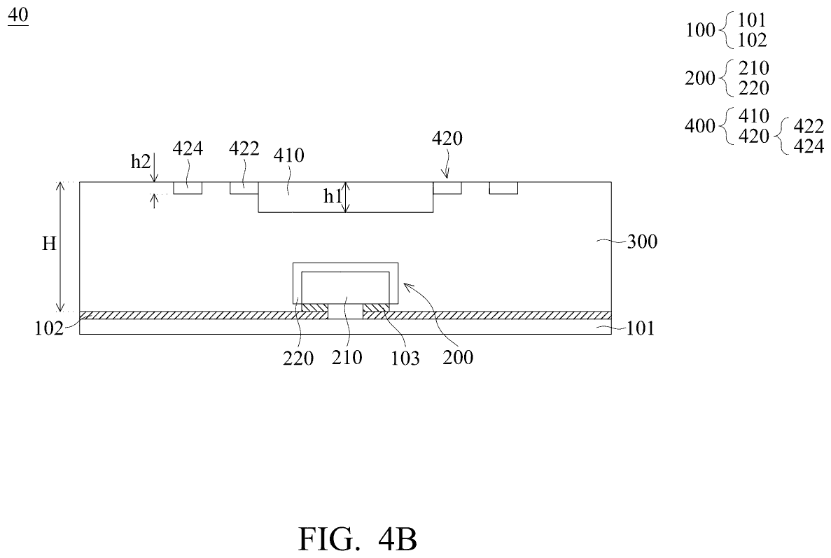

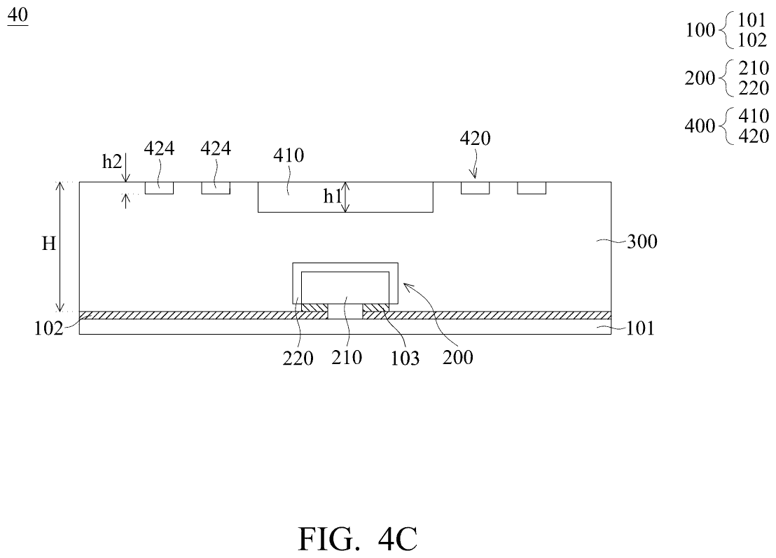

FIG. 4A is a three-dimensional schematic diagram of a light emitting module 40 according to some embodiments of the present disclosure, wherein FIG. 4B is a cross-sectional view corresponding to the line BB′ of FIG. 4A, and FIG. 4C is a cross-sectional view corresponding to the line CC′ of FIG. 4A. As shown in FIGS. 4A to 4C, the dimming structure 400 including the main dimming part 410 and the sub-dimming parts 420 may also be embedded in the encapsulant material 300. As a result, the thickness of the light emitting module 40 can be reduced.

In the embodiments of FIGS. 4B and 4C, the relationship of the geometrical dimensions between the dimming structure 400 and other elements of the light emitting module 40 is similar to that described in FIGS. 3B and 3C, and the description thereof is omitted here for brevity.

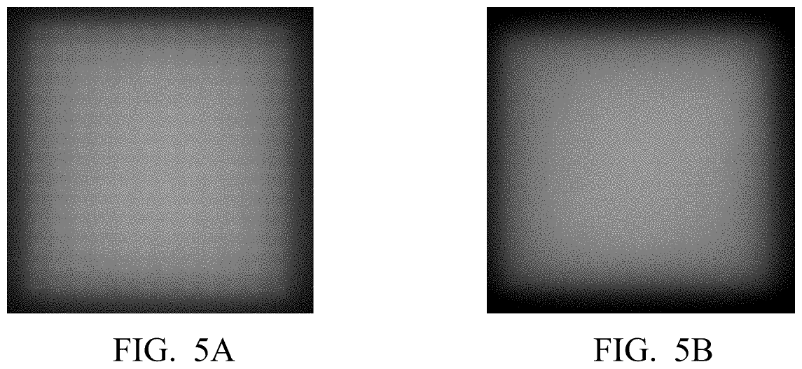

The following will illustrate the excellent effects resulted from using the dimming structures of the present disclosure with the light emitting images generated by the light emitting module during actual tests. Due to the high directivity of the light emitting diode chips, in conventional light emitting devices, the brightness of the light directly above the light emitting diode chips is relatively high, so that the light output of the light emitting devices is uneven. As shown in FIG. 5A, in the light emitting image of a conventional light emitting module, regular checkerboard-shaped mura appears. By using the dimming structures having portions with different thicknesses in the light emitting module, as shown in FIG. 5B, a light emitting image with uniform brightness can be generated, and no mura is generated therein.

The present disclosure provides a light emitting module, which can be applied to a backlight of a display, various light emitting devices, and the like. The light emitting module includes dimming structures, and each of the dimming structures is located above one of the light emitting elements, wherein the dimming structures have the effect of partially transmitting light and partially reflecting light. Since the dimming structures of the present disclosure have portions with different thicknesses, they can be used to adjust the brightness of the light above the light emitting elements, so that the light output of the light emitting module as a whole is more uniform. Therefore, the light emitting module of the present disclosure has excellent brightness and uniformity, and can reduce the usage of light emitting diodes, thereby reducing the manufacturing cost.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light emitting module, comprising:
a substrate;
light emitting elements disposed over the substrate;
an encapsulant material covering the light emitting elements and the substrate, the encapsulant material having an encapsulant height H; and
dimming structures disposed over the encapsulant material or embedded in the encapsulant material, wherein the dimming structures have a maximum dimming thickness h,
wherein the encapsulant thickness H and the maximum dimming thickness h satisfy the following relationship: 0.01≤h/H≤1.

2. The light emitting module as claimed in claim 1, wherein each of the dimming structures is located above one of the light emitting elements.

3. The light emitting module as claimed in claim 1, wherein each of the dimming structures has an outer diameter D, and the outer diameter D, the encapsulant thickness H and the maximum dimming thickness h satisfy the following relationship:
0<(H+h)/D<1.

4. The light emitting module as claimed in claim 1, wherein a spacing P between the neighboring light emitting elements and an outer diameter D of each of the dimming structures satisfy the following relationship: 0<D/P<1.

5. The light emitting module as claimed in claim 1, wherein a thickness W of the light emitting elements is smaller than an outer diameter D of the dimming structures.

6. The light emitting module as claimed in claim 1, wherein the encapsulant thickness H and the maximum dimming thickness h satisfy the following relationship:
0.1≤h/H≤0.25.

7. The light emitting module as claimed in claim 1, wherein a position of the dimming structures with the maximum dimming thickness overlaps the light emitting elements in a normal direction of the substrate.

8. The light emitting module as claimed in claim 1, wherein a surface of each of the dimming structures is a curved surface with a gradient slope.

9. The light emitting module as claimed in claim 8, wherein a position of a maximum dimming thickness of each of the dimming structures corresponds to a center of the curved surface.

10. The light emitting module as claimed in claim 8, wherein a shape of the curved surface fits to a quadratic function: y=ax²+bx+c, wherein x is a position in a direction parallel to the substrate, and y is a position in a direction vertical to the substrate, and a<0.

11. The light emitting module as claimed in claim 10, wherein an absolute value of a constant term (|c|) of the quadratic function is equal to the maximum dimming thickness h.

12. The light emitting module as claimed in claim 1, wherein each of the dimming structures comprises:
a main dimming part having the maximum dimming thickness h; and
a plurality of sub-dimming parts disposed around the main dimming part, and having a smaller thickness than the maximum dimming thickness h.

13. The light emitting module as claimed in claim 12, wherein the plurality of sub-dimming parts comprise inner sub-dimming parts in contact with the main dimming part, and the plurality of sub-dimming parts and the main dimming part together form a stepped profile in a cross-sectional view.

14. The light emitting module as claimed in claim 12, wherein the plurality of sub-dimming structures comprises outer sub-dimming parts separated from the main dimming part.

15. The light emitting module as claimed in claim 12, wherein an outer diameter of the main dimming part is larger than a width of the light emitting elements.

16. The light emitting module as claimed in claim 1, wherein a refractive index inside the dimming structures is uniform.

17. The light emitting module as claimed in claim 1, wherein the dimming structures comprise a reflective material and a resin material.

18. The light emitting module as claimed in claim 1, wherein the light emitting elements comprise multiple light emitting diode chips or multiple chip-scale package light emitting diodes (CSP LEDs).

19. The light emitting module as claimed in claim 1, wherein the substrate has integrated circuit chips, and each of the integrated circuit chips controls the light emitting elements.

20. The light emitting module as claimed in claim 1, wherein the dimming structures comprises portions with different thicknesses.
